(19) United States
(12) Patent Application Publication
(10) Pub. No.: US 2026/0339160 A1
(43) Pub. Date: Oct. 29, 2026

(54) OPTICAL MODULATOR AND OPTICAL MODULATOR-INTEGRATED LASER DEVICE

(71) Applicant: SUMITOMO ELECTRIC DEVICE INNOVATIONS, INC., Yokohama-shi (JP)

(72) Inventor: Hiromitsu KAWAMURA, Kanagawa (JP)

(73) Assignee: SUMITOMO ELECTRIC DEVICE INNOVATIONS, INC., Yokohama-shi (JP)

(21) Appl. No.: 19/653,364

(22) Filed: Apr. 21, 2026

(30) Foreign Application Priority Data
Apr. 25, 2025 (JP) 2025-072912

(51) Int. Cl. G02F 1/225; G02F 1/01; G02F 1/015; G02F 1/025; H01S 5/026

(52) U.S. Cl. CPC G02F 1/225; G02F 1/0121; G02F 1/0157; G02F 1/025; H01S 5/0265

(57) ABSTRACT

An optical modulator includes a semi-insulating or insulating substrate; an optical splitter that is provided on the substrate and splits input light; a first optical modulator of an electro-absorption type that is provided on the substrate and is configured to modulate, by a first modulation signal, first light output from the optical splitter; a second optical modulator of an electro-absorption type that is provided on the substrate and is configured to modulate, by a second modulation signal that is in the same phase as or in inverted phase to the first modulation signal, second light output from the optical splitter; and an optical combiner that is provided on the substrate and is configured to combine the first light output from the first optical modulator and the second light output from the second optical modulator.

### CROSS REFERENCE TO RELATED APPLICATION

Priority is claimed on Japanese Patent Application No. 2025-072912, filed on Apr. 25, 2025, the entire content of which is incorporated herein by reference.

### TECHNICAL FIELD

The present disclosure relates to an optical modulator and an optical modulator-integrated laser device.

### BACKGROUND

Japanese Unexamined Patent Publication No. 2002-277840 discloses an optical modulator-integrated laser device including a laser section and an optical modulator of an electro-absorption type. The optical modulator includes an n-electrode and a p-electrode. A non-inverted-phase signal and an inverted-phase signal constituting a differential signal are input to the n-electrode and the p-electrode, respectively.

### SUMMARY

An optical modulator according to one embodiment of the present disclosure includes a semi-insulating or insulating substrate; an optical splitter that is provided on the substrate and splits input light; a first optical modulator of an electro-absorption type that is provided on the substrate and is configured to modulate, by a first modulation signal, first light output from the optical splitter; a second optical modulator of an electro-absorption type that is provided on the substrate and is configured to modulate, by a second modulation signal that is in the same phase as or in inverted phase to the first modulation signal, second light output from the optical splitter; and an optical combiner that is provided on the substrate and is configured to combine the first light output from the first optical modulator and the second light output from the second optical modulator.

### BRIEF DESCRIPTION OF THE DRAWINGS

FIG. 1 is a plan view illustrating an optical modulator-integrated semiconductor laser device according to an embodiment.

FIG. 2 is a schematic view illustrating a cross-section taken along line II-II illustrated in FIG. 1.

FIG. 3 is a circuit diagram illustrating an equivalent circuit of an optical modulator of the embodiment.

FIG. 4 is a graph illustrating a time waveform of a first modulation signal applied to a first optical modulator, and a time waveform of a second modulation signal applied to a second optical modulator.

FIG. 5 is a plan view illustrating an optical modulator-integrated semiconductor laser device according to the first modification example.

FIG. 6 is a circuit diagram illustrating an equivalent circuit of an optical modulator of the first modification example.

FIG. 7 is a circuit diagram illustrating an equivalent circuit of the optical modulator of the first modification example.

FIG. 8 is a plan view illustrating an optical modulator-integrated semiconductor laser device according to the second modification example.

FIG. 9 is a schematic view illustrating a cross-section of the optical modulator-integrated semiconductor laser device taken along line IX-IX in FIG. 8.

FIG. 10 is a plan view illustrating an optical modulator-integrated semiconductor laser device according to the third modification example.

FIG. 11 is a plan view illustrating an optical modulator-integrated semiconductor laser device according to the third modification example.

FIG. 12 is a plan view illustrating an optical modulator-integrated semiconductor laser device according to a fourth modification example.

FIG. 13 is a plan view illustrating an optical modulator-integrated semiconductor laser device according to a fifth modification example.

FIG. 14 is a circuit diagram illustrating an equivalent circuit of an optical modulator according to the fifth modification example.

FIG. 15 is a graph illustrating a time waveform of a first modulation signal applied to a first optical modulator, and a time waveform of a second modulation signal applied to a second optical modulator.

FIG. 16 is a view illustrating an optical splitter including a multi-mode interference coupler.

FIG. 17 is a view illustrating an optical combiner including a multi-mode interference coupler.

FIG. 18 is a plan view illustrating an optical modulator-integrated semiconductor laser device according to a modification example.

### DETAILED DESCRIPTION

An object of the present disclosure is to provide an optical modulator of an electro-absorption type and an optical modulator-integrated laser device capable of improving the quality of an optical signal.

### Description of embodiment of present disclosure

First, the contents of an embodiment of the present disclosure will be listed and described. [1] An optical modulator according to one embodiment of the present disclosure includes a semi-insulating or insulating substrate; an optical splitter that is provided on the substrate and splits input light; a first optical modulator of an electro-absorption type that is provided on the substrate and modulates, by a first modulation signal, first light output from the optical splitter; a second optical modulator of an electro-absorption type that is provided on the substrate and modulates, by a second modulation signal that is in the same phase as or in inverted phase to the first modulation signal, second light output from the optical splitter; and an optical combiner that is provided on the substrate and combines the first light output from the first optical modulator and the second light output from the second optical modulator.

[2] In the optical modulator according to [1] above, one or both of the optical splitter and the optical combiner may include a Y-shaped optical waveguide.

[3] In the optical modulator according to [1] above, one or both of the optical splitter and the optical combiner may include a directional coupler.

[4] In the optical modulator according to [1] above, one or both of the optical splitter and the optical combiner may include a multi-mode interference coupler.

[5] The optical modulator according to any one of [1] to [4] above may further include at least one termination resistor that is provided on the substrate and terminates the first modulation signal and the second modulation signal.

[6] In the optical modulator according to any one of [1] to [5] above, both the first optical modulator and the second optical modulator may extend along a first direction, and be disposed side by side in a second direction intersecting the first direction. Further, the optical modulator may further include a semiconductor section extending along the first direction and set to a reference potential, in a region on the substrate that is located between the first optical modulator and the second optical modulator in the second direction.

[7] The optical modulator according to any one of [1] to [6] above may further include a heater provided on an optical path between the optical splitter and the first optical modulator or on an optical path between the first optical modulator and the optical combiner.

[8] In the optical modulator according to any one of [1] to [7] above, a trench that reaches the substrate may be formed between the first optical modulator and the second optical modulator, and the first optical modulator and the second optical modulator may be electrically isolated from each other by the trench.

[9] In the optical modulator according to any one of [1] to [8] above, the first optical modulator and the second optical modulator may be made of an InP-based semiconductor or a Si-based semiconductor.

[10] An optical modulator-integrated laser device according to one embodiment of the present disclosure includes the optical modulator according to any one of [1] to [9] above; and a laser section that is provided on the substrate and outputs laser light. The input light of the optical splitter is the laser light.

[11] The optical modulator-integrated laser device according to above may further include a semiconductor optical amplifier that is provided on the substrate, receives, from the optical combiner, the first light and the second light that are combined, and amplifies and outputs the first light and the second light that are combined.

[12] In the optical modulator-integrated laser device according to above, the first optical modulator and the second optical modulator may be made of an InP-based semiconductor or a Si-based semiconductor.

### Details of Embodiments of the Present Disclosure

A specific example of the present disclosure will be described below with reference to the drawings. The present disclosure is not limited to this example, but is defined by the claims, and is intended to encompass all modifications within the meaning and scope equivalent to the claims. In the following description, the same reference signs are assigned to the same elements in the description of the drawings, and a redundant description thereof is omitted. In the following description, the term “connection” refers to an electrical connection.

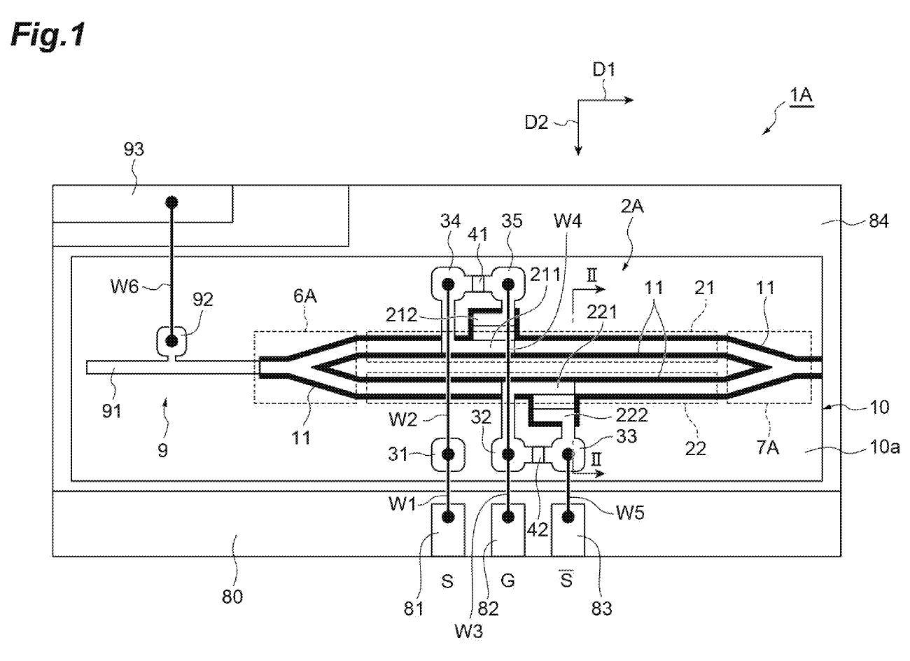

FIG. 1 is a plan view illustrating an optical modulator-integrated semiconductor laser device (hereinafter, simply referred to as a laser device) 1A according to an embodiment of the present disclosure. The laser device 1A of the present embodiment includes a substrate 10, an optical modulator 2A, and a laser section 9. The optical modulator 2A and the laser section 9 are monolithically provided on the common substrate 10. The optical modulator 2A and the laser section 9 are adjacent to each other along an optical waveguide direction on the substrate 10. The laser section 9 outputs laser light. The optical modulator 2A receives laser light from the laser section 9. The substrate 10 is a semi-insulating or insulating substrate. In one example, the substrate 10 is a semi-insulating InP substrate.

The laser device 1A is mounted on a carrier 80. A ground pattern 84 and a bias pattern 93 are provided on the main surface of the carrier 80. Furthermore, a non-inverted-phase signal wiring pattern 81, a ground wiring pattern 82, and an inverted-phase signal wiring pattern 83 are provided on the main surface of the carrier 80. The laser device 1A is mounted on the ground pattern 84, and the back surface of the laser device 1A is bonded to the ground pattern 84. The non-inverted-phase signal wiring pattern 81, the ground wiring pattern 82, the inverted-phase signal wiring pattern 83, and the bias pattern 93 are disposed at a peripheral edge portion of the ground pattern 84.

The laser section 9 includes an electrode 91 and an electrode pad 92. The electrode 91 is an electrode for supplying a bias current to an active layer (not illustrated) of the laser section 9. The electrode 91 extends along a first direction D1 (optical waveguide direction). The electrode pad 92 is disposed on a lateral side of the electrode 91, and is connected to the electrode 91. The electrode pad 92 is connected to the bias pattern 93 by a bonding wire W6. A bias current is supplied from the bias pattern 93 to the electrode 91 via the bonding wire W6 and the electrode pad 92.

The optical modulator 2A includes an optical splitter 6A, a first optical modulator 21, a second optical modulator 22, and an optical combiner 7A. The optical splitter 6A is provided on the substrate 10, and splits input light into two lights. The splitting ratio of the optical splitter 6A is, for example, 1:1, but is not limited thereto. The optical splitter 6A of the present embodiment is a Y-shaped optical waveguide. The first optical modulator 21 is, for example, an optical modulator of an electro-absorption (EA) type that is provided on the substrate 10 and modulates, by a first modulation signal, first light output from the optical splitter 6A. The first modulation signal is, for example, a non-inverted-phase signal. The second optical modulator 22 is an optical modulator of an electro-absorption (EA) type that is provided on the substrate 10 and modulates, by a second modulation signal, second light output from the optical splitter 6A. The second modulation signal is, for example, an inverted-phase signal. Both the first optical modulator 21 and the second optical modulator 22 extend along the first direction D1, and are disposed side by side in a second direction D2 intersecting the first direction D1. The optical combiner 7A is provided on the substrate 10, and combines the first light output from the first optical modulator 21 and the second light output from the second optical modulator 22. The optical combiner 7A of the present embodiment is a Y-shaped optical waveguide.

An optical modulator of an electro-absorption type is an optical modulator that utilizes the Franz-Keldysh effect. That is, the wavelength corresponding to an energy bandgap (fundamental absorption edge) shifts toward a longer wavelength side, thereby changing the amount of light absorption and modulating the light intensity. In contrast, an optical modulator of a Mach-Zehnder type also exists. An optical modulator of a Mach-Zehnder type modulates light by changing the refractive indices of two optical paths by an electro-optic effect to generate a phase difference between the optical paths. Thus, a configuration in which light is split into "two optical paths" and is phase-modulated is common in optical modulators of a Mach-Zehnder type. However, “one optical path” is generally employed in optical modulators of an electro-absorption type. The present disclosure is characterized by having a configuration in which light is split into "two optical paths", having an operating principle completely different from that of optical modulators of a Mach-Zehnder type, and performing modulation using an optical modulator of an electro-absorption type.

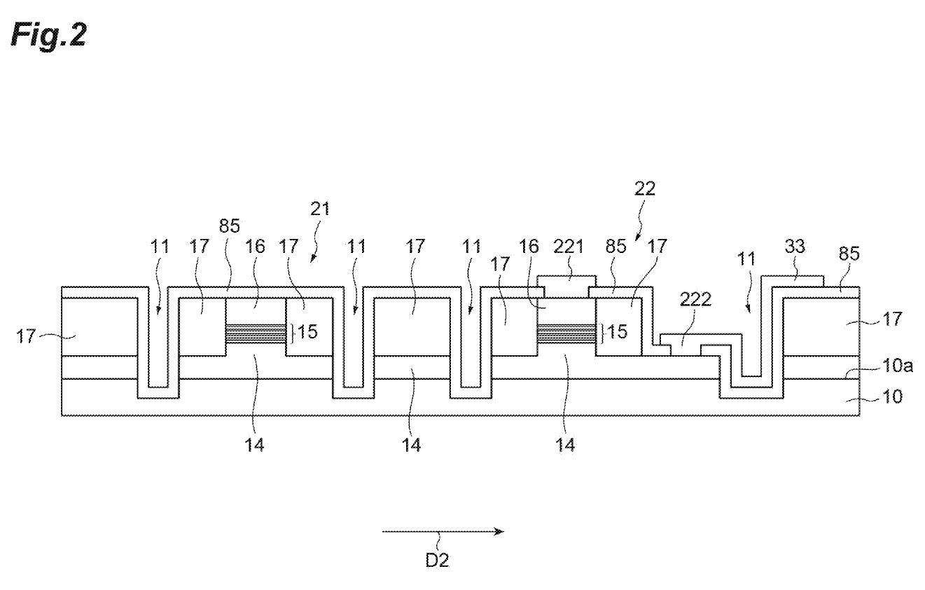

FIG. 2 is a schematic view illustrating a cross-section taken along line II-II illustrated in FIG. 1. Each of the first optical modulator 21 and the second optical modulator 22 includes a first cladding layer 14, a light absorption layer 15, and a second cladding layer 16. The first cladding layer 14, the light absorption layer 15, and the second cladding layer 16 of the present embodiment are III-V compound semiconductor layers.

The first cladding layer 14 is an n-type semiconductor layer provided on a main surface 10a of the substrate 10. In one example, the first cladding layer 14 is an n-type InP layer. The light absorption layer 15 is provided on the first cladding layer 14. The bandgap of the light absorption layer 15 is smaller than the bandgap of the first cladding layer 14. The refractive index of the light absorption layer 15 is larger than the refractive index of the first cladding layer 14. The light absorption layer 15 may have a multiple quantum well structure. In one example, the light absorption layer 15 is formed by stacking InGaAsP layers or InGaAlAs layers having different compositions. The second cladding layer 16 is provided on the light absorption layer 15, and is p-type. In one example, the second cladding layer 16 is a p-type InP layer.

A part of the first cladding layer 14, the light absorption layer 15, and the second cladding layer 16 form a mesa structure extending along the first direction D1 (the optical waveguide direction). The base of the mesa structure is located in the first cladding layer 14. Therefore, the lower portion of the first cladding layer 14 also extends outward of the mesa structure in a plan view.

The optical modulator 2A further includes an insulating film 85 and buried regions 17. The buried regions 17 are provided on both sides of the mesa structure, and bury both side surfaces of the mesa structure. The buried regions 17 have insulating properties or semi-insulating properties. The buried regions 17 are, for example, semi-insulating InP regions. The material of the buried regions 17 may be the same as the material of the substrate 10, or may be different from the material of the substrate 10. The insulating film 85 is provided on the buried regions 17, and covers the buried regions 17. The insulating film 85 is, for example, a silicon compound film such as a SiO₂ film or a SiN film.

Referring again to FIG. 1, the optical modulator 2A further includes electrode pads 31, 32, 33, 34, and 35 that are metal films. The first optical modulator 21 includes an anode electrode 211 and a cathode electrode 212 in addition to the above-described configuration. The second optical modulator 22 includes an anode electrode 221 and a cathode electrode 222 in addition to the above-described configuration. The electrode pads 31, 32, and 33 are disposed on one side with respect to the first optical modulator 21 and the second optical modulator 22, and are aligned in this order along the first direction D1 (the optical waveguide direction). The electrode pads 34 and 35 are disposed on the other side with respect to the first optical modulator 21 and the second optical modulator 22, and are aligned in this order along the first direction D1 (the optical waveguide direction).

The electrode pad 31 is connected to the non-inverted-phase signal wiring pattern 81 by a bonding wire W1, and is connected to the electrode pad 34 by a bonding wire W2. That is, the bonding wire W2 straddles the first optical modulator 21 and the second optical modulator 22. The electrode pad 34 is connected to the anode electrode 211 of the first optical modulator 21. The anode electrode 211 is provided on the mesa structure of the first optical modulator 21, and is connected to the second cladding layer 16 of the first optical modulator 21. The first modulation signal (non-inverted-phase signal) input to the non-inverted-phase signal wiring pattern 81 is applied to the second cladding layer 16 of the first optical modulator 21 via the bonding wires W1 and W2 and the anode electrode 211.

The electrode pad 32 is connected to the anode electrode 221 of the second optical modulator 22. The anode electrode 221 is provided on the mesa structure of the second optical modulator 22, and is connected to the second cladding layer 16 of the second optical modulator 22. Furthermore, the electrode pad 32 is connected to the ground wiring pattern 82 by a bonding wire W3, and is connected to the electrode pad 35 by a bonding wire W4. That is, the bonding wire W4 also straddles the first optical modulator 21 and the second optical modulator 22. The electrode pad 35 is connected to the cathode electrode 212 of the first optical modulator 21. The cathode electrode 212 is provided on the first cladding layer 14 on a lateral side of the mesa structure of the first optical modulator 21, and is connected to the first cladding layer 14 of the first optical modulator 21. A reference potential input to the ground wiring pattern 82 is transmitted to the second cladding layer 16 of the second optical modulator 22 via the bonding wire W3 and the anode electrode 221. The reference potential input to the ground wiring pattern 82 is transmitted to the first cladding layer 14 of the first optical modulator 21 via the bonding wires W3 and W4 and the cathode electrode 212. A first termination resistor 41 is provided between the electrode pad 34 and the electrode pad 35. The first termination resistor 41 connects the electrode pad 34 to the electrode pad 35. The first termination resistor 41 is provided on the substrate 10, and terminates the first modulation signal. The first termination resistor 41 is provided at a position close to the electrode pad 34. A distance between the first termination resistor 41 and the electrode pad 34 is, for example, several tens of µm or less. Accordingly, the frequency characteristics of the first modulation signal are improved.

The electrode pad 33 is connected to the inverted-phase signal wiring pattern 83 by a bonding wire W5. The electrode pad 33 is connected to the cathode electrode 222 of the second optical modulator 22. As illustrated in FIG. 2, the cathode electrode 222 is provided on the first cladding layer 14 on a lateral side of the mesa structure of the second optical modulator 22, and is connected to the first cladding layer 14 of the second optical modulator 22. The second modulation signal (inverted-phase signal) input to the inverted-phase signal wiring pattern 83 is applied to the first cladding layer 14 of the second optical modulator 22 via the bonding wire W5 and the cathode electrode 222. A second termination resistor 42 is provided between the electrode pad 33 and the electrode pad 32. The second termination resistor 42 connects the electrode pad 33 to the electrode pad 32. The second termination resistor 42 is provided on the substrate 10, and terminates the second modulation signal. The second termination resistor 42 is provided at a position close to the electrode pad 33. A distance between the second termination resistor 42 and the electrode pad 33 is, for example, several tens of µm or less. Accordingly, the frequency characteristics of the second modulation signal are improved.

The resistance value of the first termination resistor 41 is determined according to the impedance of the first optical modulator 21. The resistance value of the second termination resistor 42 is determined according to the impedance of the second optical modulator 22. The resistance value of the second termination resistor 42 may be the same as or different from the resistance value of the first termination resistor 41. For example, when the splitting ratio of the optical splitter 6A is not 1:1, the impedance of the second optical modulator 22 is different from the impedance of the first optical modulator 21. In that case, the resistance value of the second termination resistor 42 is set to a value different from the resistance value of the first termination resistor 41.

The bonding wire W3 set to the reference potential is located between the bonding wire W1 that transmits the first modulation signal and the bonding wire W5 that transmits the second modulation signal. Further, the bonding wires W1, W3, and W5 extend parallel to each other. With such a configuration, the frequency characteristics of the first modulation signal and the second modulation signal are improved.

The optical modulator 2A further has a plurality of trenches (grooves) 11. As illustrated in FIG. 2, the plurality of trenches 11 reach the substrate 10 from the upper surface of the second cladding layer 16, and electrically isolate the first optical modulator 21 and the second optical modulator 22 from each other. In FIG. 1, the trenches 11 are indicated by thick lines. Specifically, the first optical modulator 21 is interposed between a pair of the trenches 11, and the second optical modulator 22 is interposed between another pair of the trenches 11. A certain spacing (for example, several µm to several tens of µm) is provided between the trench 11 on the inner side (on the side closer to the second optical modulator 22) of the pair of trenches 11 that interpose the first optical modulator 21 therebetween and the trench 11 on the inner side (on the side closer to the first optical modulator 21) of the pair of trenches 11 that interpose the second optical modulator 22 therebetween. The trench 11 on the outer side of the pair of trenches 11 that interpose the first optical modulator 21 therebetween bulges outward such that the portion of the first cladding layer 14, which is connected to the cathode electrode 212, is located between the pair of trenches 11. Similarly, the trench 11 on the outer side of the pair of trenches 11 that interpose the second optical modulator 22 therebetween bulges outward such that the portion of the first cladding layer 14, which is connected to the cathode electrode 222, is located between the pair of trenches 11. The inner surfaces of the trenches 11 are covered by the insulating film 85.

A wiring that connects the electrode pad 34 and the anode electrode 211 of the first optical modulator 21, a wiring that connects the electrode pad 35 and the cathode electrode 212 of the first optical modulator 21, a wiring that connects the electrode pad 32 and the anode electrode 221 of the second optical modulator 22, and a wiring that connects the electrode pad 33 and the cathode electrode 222 of the second optical modulator 22 are formed of metal films. These metal films extend across the trenches 11 by being provided so as to run along the side walls and bottom surfaces of the trenches 11.

The cross-sectional structures of the optical splitter 6A and the optical combiner 7A are the same as those of the optical modulator 2A described above, except that an anode electrode and a cathode electrode are not provided.

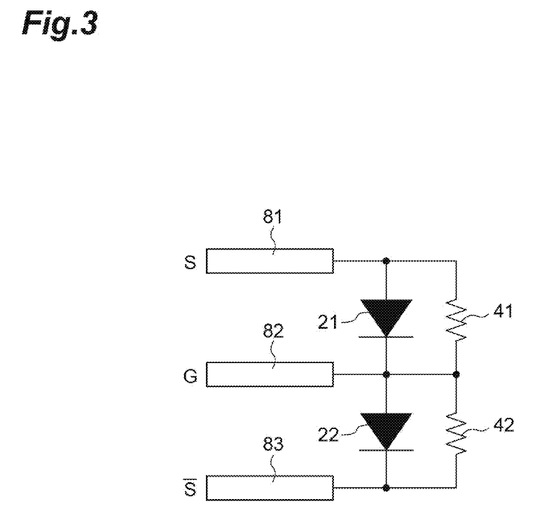

FIG. 3 is a circuit diagram illustrating an equivalent circuit of the optical modulator 2A of the present embodiment. In FIG. 3, the first optical modulator 21 and the second optical modulator 22 are indicated by diode symbols. As illustrated in FIG. 3, in the optical modulator 2A, the first optical modulator 21 and the second optical modulator 22 are connected in series in this order while oriented in the same direction. Further, the non-inverted-phase signal wiring pattern 81 is connected to the anode of the first optical modulator 21, and the inverted-phase signal wiring pattern 83 is connected to the cathode of the second optical modulator 22. The ground wiring pattern 82 is connected to the cathode of the first optical modulator 21 and the anode of the second optical modulator 22.

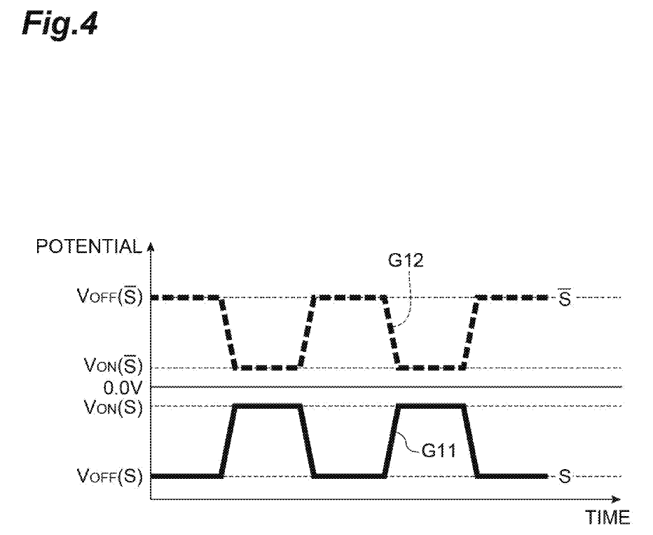

FIG. 4 is a graph illustrating a time waveform G11 of the first modulation signal applied to the first optical modulator 21, and a time waveform G12 of the second modulation signal applied to the second optical modulator 22. As illustrated in FIG. 4, the first modulation signal varies between a potential V_{OFF} and a potential V_{ON}, which is a potential higher than the potential V_{OFF}. The potential V_{OFF} and the potential V_{ON} of the first modulation signal are lower than the reference potential (0.0 V). The second modulation signal varies between a potential V_{OFF} and a potential V_{ON}, which is a potential lower than the potential V_{OFF}. The potential V_{OFF} and the potential V_{ON} of the second modulation signal are higher than the reference potential (0.0 V).

The effects obtained by the optical modulator 2A and the laser device 1A of the present embodiment described above will be described together with the problems associated with the conventional art. Conventionally, an optical modulator of an electro-absorption type is often driven by a single-phase signal. However, in recent years, it has become increasingly common to mount a plurality of optical modulators in an optical transmitter at high density and drive the optical modulators at communication speeds of several tens of Gb/s or higher. In such high-speed applications, when an optical modulator of an electro-absorption type is driven by a single-phase signal, electrical interference among a plurality of the optical modulators inside an optical transmitter is likely to occur. Even in signal transmission paths from an external circuit to the optical modulators inside the optical transmitter, signal quality is easily degraded due to common-mode noise. To address these problems, it can be considered that the optical modulator of the electro-absorption type is driven by a differential signal. However, since the optical modulator of the electro-absorption type has a diode structure including an anode and a cathode, it is difficult to drive the optical modulator of the electro-absorption type with the differential signal.

To address such a problem, the optical modulator 2A of the present embodiment includes the first optical modulator 21 and the second optical modulator 22. The input light to the optical modulator 2A is split into the first light and the second light by the optical splitter 6A, and then the first light is input to the first optical modulator 21, and the second light is input to the second optical modulator 22. Then, the first modulation signal, which is a non-inverted-phase signal, is input to the anode electrode 211 of the first optical modulator 21, and the reference potential is input to the cathode electrode 212, so that the first optical modulator 21 is driven by the non-inverted-phase signal. The reference potential is input to the anode electrode 221 of the second optical modulator 22, and the second modulation signal, which is an inverted-phase signal, is input to the cathode electrode 222, so that the second optical modulator 22 is driven in the same phase as the first optical modulator 21 by the inverted-phase signal. Accordingly, the first light and the second light are modulated in the same phase, and then the first light and the second light are combined by the optical combiner 7A. Therefore, according to the optical modulator 2A of the present embodiment, the optical modulator of an electro-absorption type can be driven by a differential signal. As a result, electrical interference among a plurality of the optical modulators can be reduced, and degradation of signal quality due to common-mode noise can be reduced. Therefore, the quality of the optical signal output from the optical modulator 2A can be improved.

To solve the above-described problem, a configuration in which the first optical modulator and the second optical modulator are arranged in series on the same optical waveguide can also be considered. According to the optical modulator 2A of the present embodiment, compared to such a configuration, electrical isolation between the first optical modulator and the second optical modulator can be increased.

As in the present embodiment, both the optical splitter 6A and the optical combiner 7A may include Y-shaped optical waveguides. In this case, light can be split or combined with a simple structure on the substrate 10. The configurations of the optical splitter 6A and the optical combiner 7A are not limited to those in the present embodiment; only one of the optical splitter 6A and the optical combiner 7A may include a Y-shaped optical waveguide, and the other may include another structure different from a Y-shaped optical waveguide.

As in the present embodiment, the optical modulator 2A may include termination resistors (the first termination resistor 41 and the second termination resistor 42) that are provided on the substrate 10, and that terminate the first modulation signal and the second modulation signal. In this case, the optical transmitter can be made more compact compared to a case where the termination resistors are provided external to the substrate 10. By shortening a wiring that connects the anode electrode 211 and the cathode electrode 212 to the first termination resistor 41 and a wiring that connects the anode electrode 221 and the cathode electrode 222 to the second termination resistor 42, the frequency characteristics of the first modulation signal and the second modulation signal can be improved. The disposition of the first termination resistor 41 and the second termination resistor 42 is not limited to the present embodiment, and for example, the first termination resistor 41 and the second termination resistor 42 may be installed on the carrier 80. The first termination resistor 41 and the second termination resistor 42 may be replaced with CR circuits, each having a complex impedance.

As in the present embodiment, the trenches 11 that reach the substrate 10 may be formed between the first optical modulator 21 and the second optical modulator 22, and the first optical modulator 21 and the second optical modulator 22 may be electrically isolated from each other by the trenches 11. In the optical modulator 2A of the present embodiment, the potential of the first optical modulator 21 is different from the potential of the second optical modulator 22. Therefore, by electrically isolating the first optical modulator 21 and the second optical modulator 22 from each other by the trenches 11, interference between the first optical modulator 21 and the second optical modulator 22 can be prevented, and the quality of the optical signal output from the optical modulator 2A can be further improved.

The laser device 1A of the present embodiment includes the laser section 9 that is provided on the substrate 10 common to the optical modulator 2A, and that outputs laser light. Further, the input light of the optical splitter 6A is the laser light from the laser section 9. According to the laser device 1A, the quality of the optical signal can be improved by including the optical modulator 2A.

### First modification example

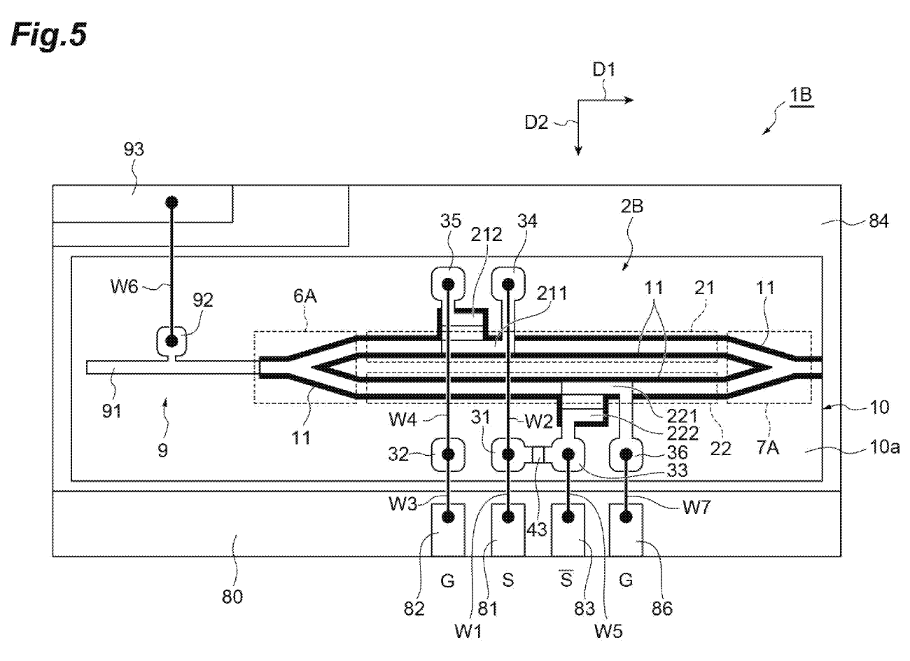

FIG. 5 is a plan view illustrating a laser device 1B according to the first modification example. The laser device 1B according to the present modification example differs from the laser device 1A of the above-described embodiment in the following points, and is identical to the laser device 1A in other points. The laser device 1B according to the present modification example includes an optical modulator 2B instead of the optical modulator 2A of the above-described embodiment. The optical modulator 2B further includes an electrode pad 36 in addition to the electrode pads 31, 32, and 33 of the optical modulator 2A. The optical modulator 2B includes a termination resistor 43 instead of the first termination resistor 41 and the second termination resistor 42. A ground wiring pattern 86 is further provided on the main surface of the carrier 80.

The electrode pads 32, 31, 33, and 36 are disposed on one side with respect to the first optical modulator 21 and the second optical modulator 22, and are aligned in this order along the first direction D1 (the optical waveguide direction). That is, the electrode pad 31 is disposed between the electrode pad 32 and the electrode pad 33. The electrode pads 35 and 34 are disposed on the other side with respect to the first optical modulator 21 and the second optical modulator 22, and are aligned in this order along the first direction D1 (the optical waveguide direction). That is, the electrode pad 35 is disposed on the optical splitter 6A side when viewed from the electrode pad 34.

The termination resistor 43 is provided between the electrode pad 31 and the electrode pad 33. The termination resistor 43 connects the electrode pad 31 to the electrode pad 33. The termination resistor 43 is provided on the substrate 10, and terminates both the first modulation signal and the second modulation signal with respect to a reference potential that is virtually formed at the center of the termination resistor 43. The termination resistor 43 is provided at a position close to both the electrode pad 31 and the electrode pad 33. A distance between the termination resistor 43 and the electrode pads 31 and 33 is, for example, several tens of µm or less. Accordingly, the frequency characteristics of the first modulation signal and the second modulation signal are improved.

The electrode pad 36 is connected to the ground wiring pattern 86 by a bonding wire W7. In addition, the electrode pad 36 is connected to the anode electrode 221 of the second optical modulator 22. The electrode pad 32 is not connected to the anode electrode 221 of the second optical modulator 22.

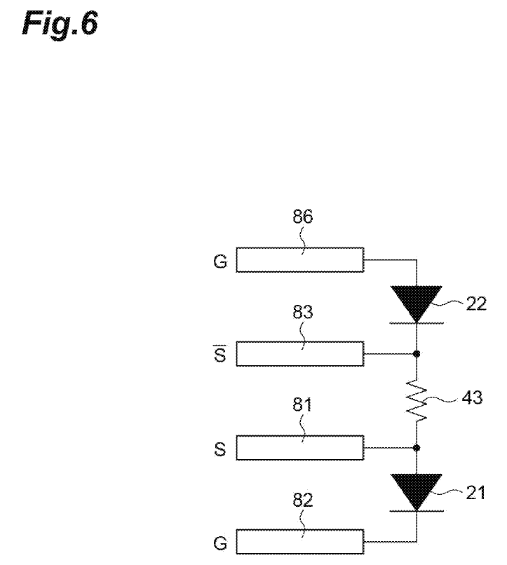

FIG. 6 is a circuit diagram illustrating an equivalent circuit of the optical modulator 2B of the present modification example. In FIG. 6, the first optical modulator 21 and the second optical modulator 22 are indicated by diode symbols. As illustrated in FIG. 6, in the optical modulator 2B, the second optical modulator 22 and the first optical modulator 21 are connected in series in this order while oriented in the same direction. The termination resistor 43 is connected in series between the first optical modulator 21 and the second optical modulator 22. Further, the ground wiring pattern 86 is connected to the anode of the second optical modulator 22, and the inverted-phase signal wiring pattern 83 is connected to the cathode of the second optical modulator 22. The non-inverted-phase signal wiring pattern 81 is connected to the anode of the first optical modulator 21, and the ground wiring pattern 82 is connected to the cathode of the first optical modulator 21. In the present modification example, a time waveform of the first modulation signal applied to the first optical modulator 21 and a time waveform of the second modulation signal applied to the second optical modulator 22 are the same as those in the above-described embodiment (see FIG. 4).

According to the present modification example, the same effects as those in the above-described embodiment can be obtained. That is, according to the optical modulator 2B of the present modification example, the optical modulator of an electro-absorption type can be driven by a differential signal. As a result, electrical interference among a plurality of the optical modulators can be reduced, and further, degradation of signal quality due to common-mode noise can be reduced. Therefore, the quality of the optical signal output from the optical modulator 2B can be improved.

The bonding wire W3 set to the reference potential extends parallel to the bonding wire W1 that transmits the first modulation signal. Similarly, the bonding wire W7 set to the reference potential extends parallel to the bonding wire W5 that transmits the second modulation signal. With such a configuration, the frequency characteristics of the first modulation signal and the second modulation signal are improved.

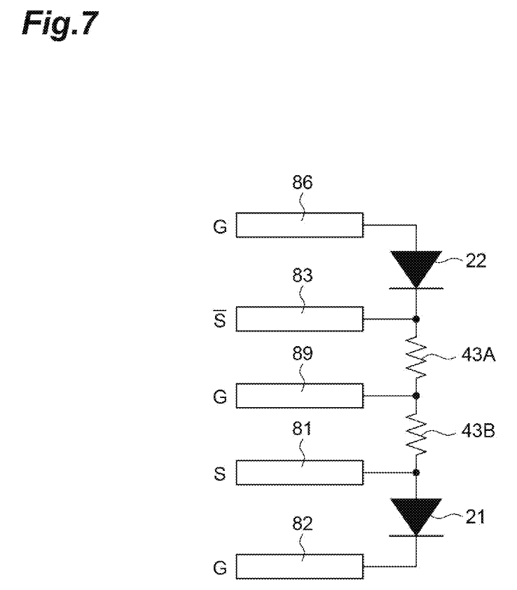

As illustrated in FIG. 7, the termination resistor 43 may be split into two termination resistors 43A and 43B connected in series to each other, and a ground wiring pattern 89 may be connected to a node between the termination resistor 43A and the termination resistor 43B via a bonding wire. The ground wiring pattern 89 is disposed between the non-inverted-phase signal wiring pattern 81 and the inverted-phase signal wiring pattern 83 on the carrier 80. In this case, a bonding wire set to the reference potential is located between the bonding wire W1 that transmits the first modulation signal and the bonding wire W5 that transmits the second modulation signal. Thus, the frequency characteristics of the first modulation signal and the second modulation signal are further improved.

As in the present modification example, the optical modulator 2B may include the termination resistor 43 that is provided on the substrate 10, and that terminates the first modulation signal and the second modulation signal. In this case, the optical transmitter can be made more compact compared to a case where the termination resistor 43 is provided external to the substrate 10. By shortening a wiring that connects the anode electrode 211 to the termination resistor 43 and a wiring that connects the cathode electrode 222 to the termination resistor 43, the frequency characteristics of the first modulation signal and the second modulation signal can be improved. The disposition of the termination resistor 43 is not limited to the present modification example, and for example, the termination resistor 43 may be installed on the carrier 80. The termination resistor 43 may be replaced with a CR circuit having a complex impedance.

### Second modification example

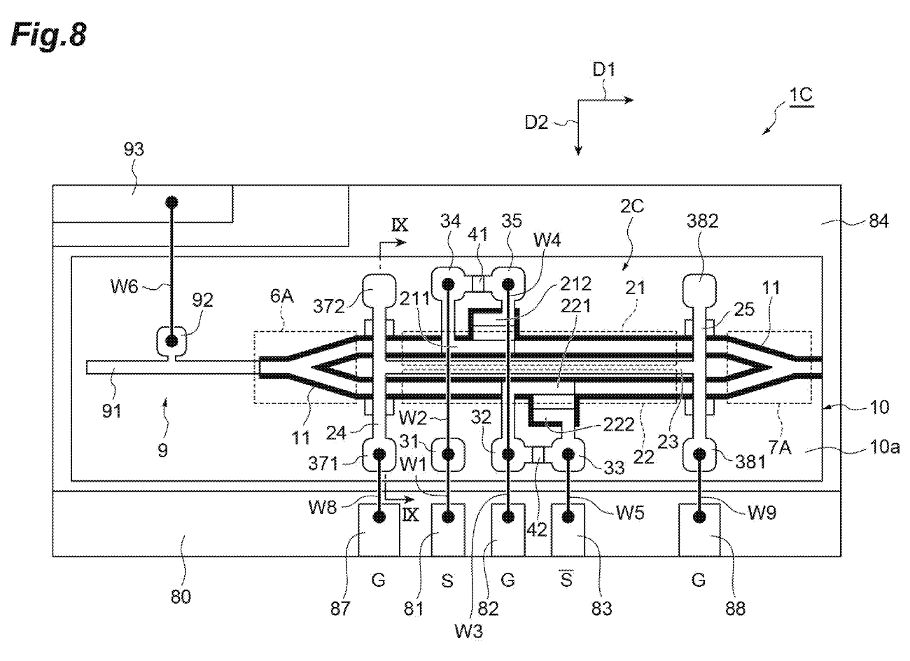

FIG. 8 is a plan view illustrating a laser device 1C according to the second modification example. The laser device 1C according to the present modification example differs from the laser device 1A of the above-described embodiment in the following points, and is identical to the laser device 1A in other points. The laser device 1C according to the present modification example includes an optical modulator 2C instead of the optical modulator 2A of the above-described embodiment. The optical modulator 2C further includes electrode pads 371, 372, 381, and 382. The optical modulator 2C further includes wirings 23, 24, and 25. Ground wiring patterns 87 and 88 are further provided on the main surface of the carrier 80.

The electrode pads 371, 31, 32, 33, and 381 are disposed on one side with respect to the first optical modulator 21 and the second optical modulator 22, and are aligned in this order along the first direction D1 (the optical waveguide direction). That is, the electrode pad 371 is disposed on the optical splitter 6A side when viewed from the electrode pad 31. The electrode pad 381 is disposed on the optical combiner 7A side when viewed from the electrode pad 33. The electrode pads 372, 34, 35, and 382 are disposed on the other side with respect to the first optical modulator 21 and the second optical modulator 22, and are aligned in this order along the first direction D1 (the optical waveguide direction). That is, the electrode pad 372 is disposed on the optical splitter 6A side when viewed from the electrode pad 34. The electrode pad 382 is disposed on the optical combiner 7A side when viewed from the electrode pad 35.

The wiring 24 is located between the optical splitter 6A and both the first optical modulator 21 and the second optical modulator 22 in the first direction D1 (the optical waveguide direction). The wiring 24 extends along the second direction D2, and connects the electrode pad 371 to the electrode pad 372. The wiring 24 is disposed across a plurality of the trenches 11. The electrode pad 371 is connected to the ground wiring pattern 87 by a bonding wire W8. A reference potential input to the ground wiring pattern 87 is transmitted to the wiring 24 via the bonding wire W8 and the electrode pad 371.

The wiring 25 is located between both the first optical modulator 21 and the second optical modulator 22 and the optical combiner 7A in the first direction D1 (the optical waveguide direction). The wiring 25 extends along the second direction D2, and connects the electrode pad 381 to the electrode pad 382. The wiring 25 is disposed across a plurality of the trenches 11. The electrode pad 381 is connected to the ground wiring pattern 88 by a bonding wire W9. The reference potential input to the ground wiring pattern 88 is transmitted to the wiring 25 via the bonding wire W9 and the electrode pad 381. The resistance of the first cladding layer 14 directly below the waveguide is approximately 100 Ω to several kΩ, and is sufficiently large compared to the impedance (for example, several tens of Ω) of the first optical modulator 21 and the second optical modulator 22 during operation of the first optical modulator 21 and the second optical modulator 22. Therefore, sufficient electrical isolation is ensured between the non-inverted-phase signal and the inverted-phase signal constituting the differential signal and between the differential signal and the ground. In particular, when the modulation frequency becomes high, interference between the non-inverted-phase signal and the inverted-phase signal increases due to electrostatic induction caused by stray capacitance or the like. To reduce such interference due to electrostatic induction or the like and further increase electrical isolation, it can be considered to increase a distance between the non-inverted-phase signal and the inverted-phase signal and a distance between the differential signal and the ground, or to provide a ground between the non-inverted-phase signal and the inverted-phase signal. However, due to dimensional constraints imposed by the electrodes and the optical paths or the like, it may be difficult to sufficiently increase electrical isolation. In the present structure, by providing the wiring 25, interference due to electrostatic induction or the like can be easily reduced, and electrical isolation can be further increased.

The wiring 23 extends along the first direction D1 (the optical waveguide direction). The first end of the wiring 23 is connected to the wiring 24, and the second end of the wiring 23 is connected to the wiring 25. The wiring 23 is disposed between the first optical modulator 21 and the second optical modulator 22 in the second direction D2.

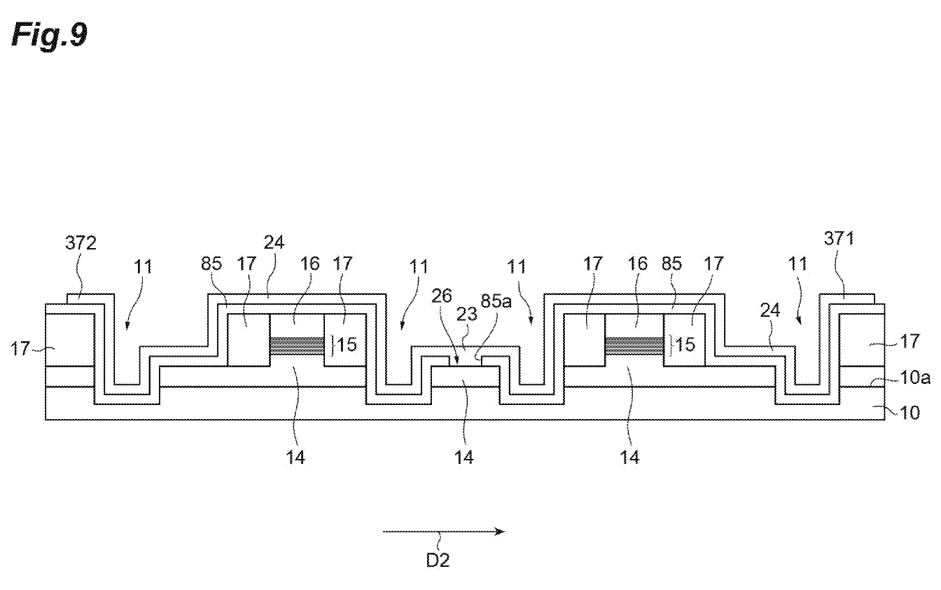

FIG. 9 is a schematic view illustrating a cross-section of the laser device 1C taken along line IX-IX in FIG. 8, and mainly illustrates a cross-section along the wiring 24. The optical modulator 2C of the present modification example includes a semiconductor section 26. The semiconductor section 26 is provided in a region on the substrate 10 that is located between the first optical modulator 21 and the second optical modulator 22 in the second direction D2. The semiconductor section 26 includes a part of the substrate 10 and the first cladding layer 14. The semiconductor section 26 is interposed between the trench 11 on the inner side (on the side closer to the second optical modulator 22) of the pair of trenches 11 that interpose the first optical modulator 21 therebetween and the trench 11 on the inner side (on the side closer to the first optical modulator 21) of the pair of trenches 11 that interpose the second optical modulator 22 therebetween, thereby having a mesa shape extending along the first direction D1. The insulating film 85 has an opening 85a provided on the semiconductor section 26 and extending along the first direction D1, and the wiring 23 is in contact with the first cladding layer 14 through the opening 85a. Accordingly, the potential of the first cladding layer 14 of the semiconductor section 26 is set to the reference potential. Although not illustrated, the wiring 25 is also formed in the same manner as the wiring 24.

According to the optical modulator 2C of the second modification example described above, the same effects as those in the above-described embodiment can be obtained. That is, according to the optical modulator 2C of the present modification example, the optical modulator of an electro-absorption type can be driven by a differential signal. As a result, electrical interference among a plurality of the optical modulators can be reduced, and degradation of signal quality due to common-mode noise can be reduced. Therefore, the quality of the optical signal output from the optical modulator 2C can be improved.

As in the present modification example, the semiconductor section 26 extending along the first direction D1 and set to the reference potential may be provided in a region on the substrate 10 between the first optical modulator 21 and the second optical modulator 22 in the second direction D2. Therefore, by increasing electrical isolation between the first optical modulator 21 and the second optical modulator 22, interference between the first optical modulator 21 and the second optical modulator 22 can be prevented, and the quality of the optical signal output from the optical modulator 2C can be further improved.

### Third modification example

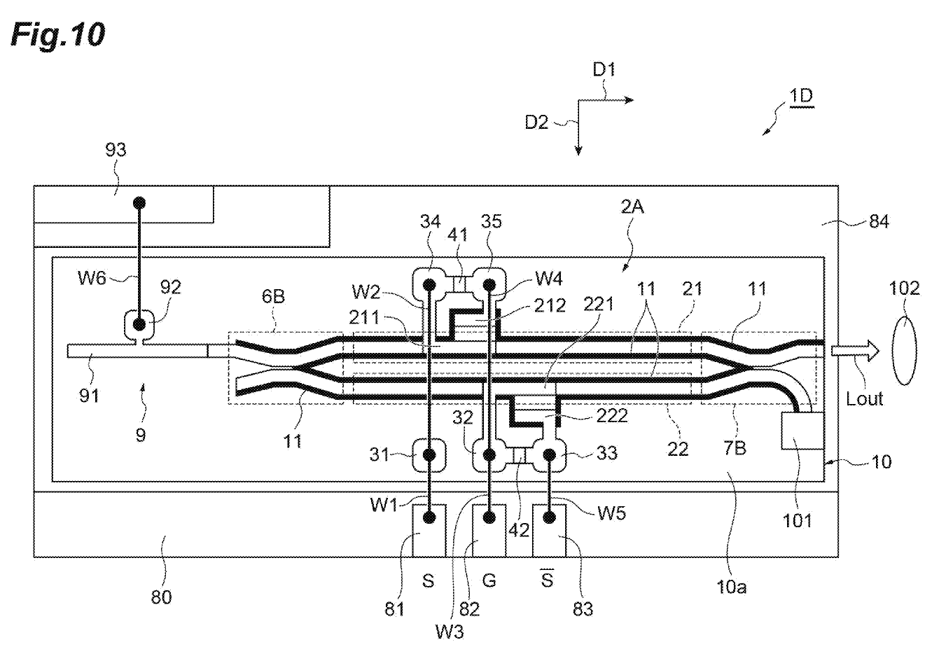

FIG. 10 is a plan view illustrating a laser device 1D according to the third modification example. The laser device 1D according to the present modification example differs from the laser device 1A of the above-described embodiment in the following points, and is identical to the laser device 1A in other points. The laser device 1D according to the present modification example includes an optical splitter 6B and an optical combiner 7B instead of the optical splitter 6A and the optical combiner 7A of the above-described embodiment.

The optical splitter 6B is provided on the substrate 10, and splits input light into two lights. The splitting ratio of the optical splitter 6B is, for example, 1:1, but is not limited thereto. The optical splitter 6B of the present modification example is a directional coupler. The first optical modulator 21 modulates the first light output from the optical splitter 6B. The second optical modulator 22 modulates the second light output from the optical splitter 6B. The optical combiner 7B is provided on the substrate 10, and combines the first light output from the first optical modulator 21 and the second light output from the second optical modulator 22. The optical combiner 7B of the present modification example is a directional coupler.

The combined light output from one of the two output ends of the optical combiner 7B is output from the laser device 1D as output light Lout, and is collimated, for example, by a lens 102. The combined light output from the other of the two output ends of the optical combiner 7B is input to a monitor photodiode 101. The monitor photodiode 101 is provided on the substrate 10, and detects the light intensity of the combined light.

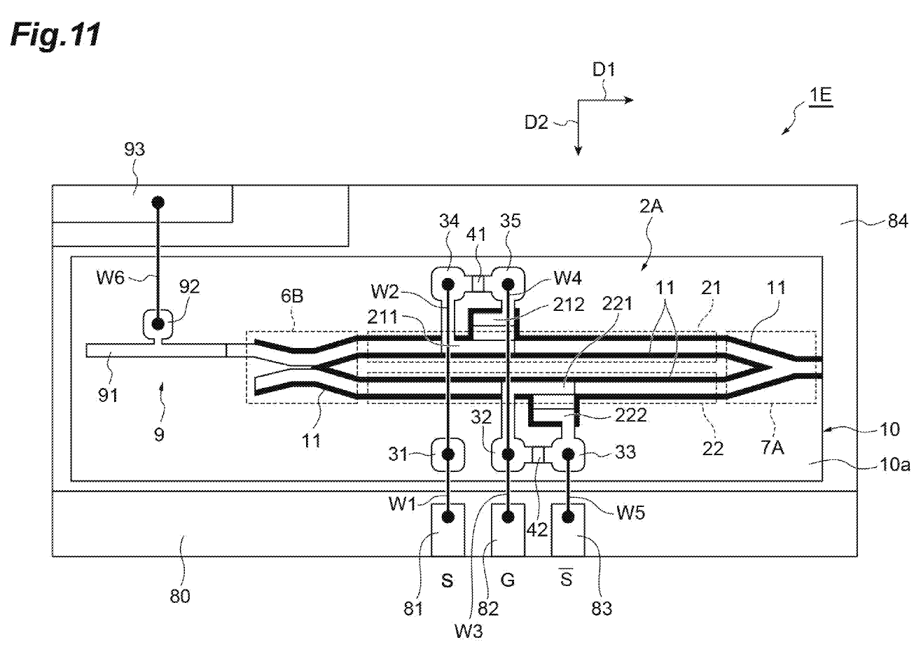

As in the present modification, both the optical splitter 6B and the optical combiner 7B may include directional couplers. In this case, light can be split or combined with a simple structure on the substrate 10. The configurations of the optical splitter 6B and the optical combiner 7B are not limited to those in the present modification example; only one of the optical splitter 6B and the optical combiner 7B may include a directional coupler, and the other may include another structure different from a directional coupler. For example, as in a laser device 1E illustrated in FIG. 11, the optical splitter 6B including a directional coupler and the optical combiner 7A including a Y-shaped optical waveguide may be combined.

### Fourth modification example

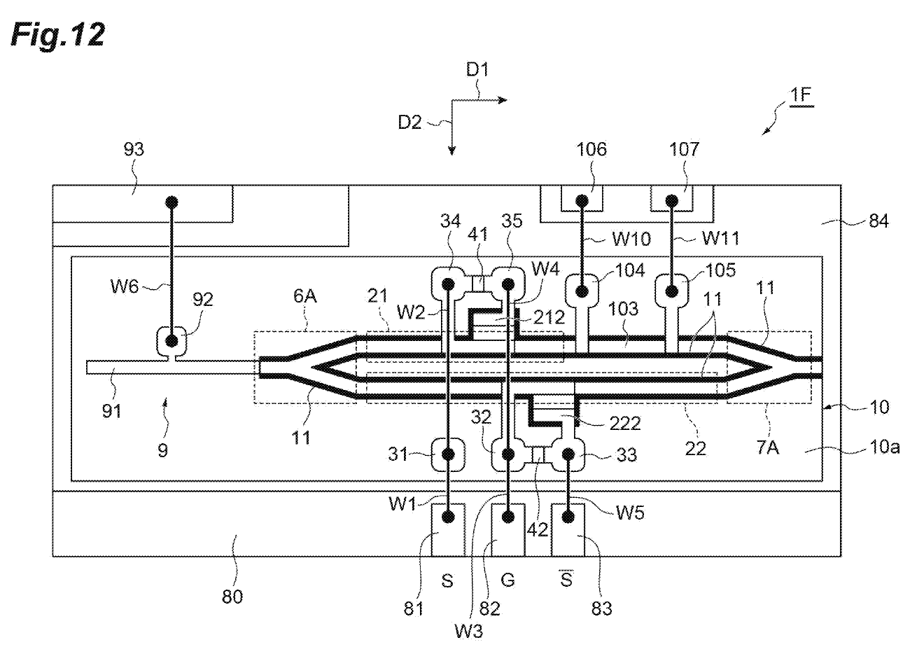

FIG. 12 is a plan view illustrating a laser device 1F according to a fourth modification example. The laser device 1F according to the present modification example differs from the laser device 1A of the above-described embodiment in the following points, and is identical to the laser device 1A in other points. The laser device 1F according to the present modification example further includes a heater 103, an electrode pad 104, and an electrode pad 105 in addition to the configuration of the laser device 1A of the above-described embodiment. Heater wiring patterns 106 and 107 are further provided on the main surface of the carrier 80.

The heater 103 extends along the first direction D1, and is provided on the optical path between the first optical modulator 21 and the optical combiner 7A (on the mesa structure and in a region between the pair of trenches 11). The disposition of the heater 103 is not limited thereto, and for example, the heater 103 may be provided on the optical path between the optical splitter 6A and the first optical modulator 21.

The electrode pad 104 is connected to the first end of the heater 103, and is connected to the heater wiring pattern 106 by a bonding wire W10. The electrode pad 105 is connected to the second end of the heater 103, and is connected to the heater wiring pattern 107 by a bonding wire W11. Electric power for causing the heater 103 to generate heat is supplied from outside the carrier 80 between the heater wiring pattern 106 and the heater wiring pattern 107.

The heater 103 includes, for example, a passivation film such as a SiO₂ film or a SiN film provided on the mesa structure, and a resistor containing nickel-chromium (NiCr), titanium-tungsten (TiW), or platinum (Pt) and provided on the passivation film. A wiring that connects the first end of the heater 103 to the electrode pad 104 and a wiring that connects the second end of the heater 103 to the electrode pad 105 are, for example, gold (Au) films. The length of the resistor in the first direction D1 is, for example, approximately several hundred µm.

As in the present modification example, the heater 103 may be provided on the optical path between the optical splitter 6A and the first optical modulator 21 or on the optical path between the first optical modulator 21 and the optical combiner 7A. Accordingly, the refractive index of the optical waveguide located below the heater 103 can be changed to adjust the phase difference between the first light and the second light. That is, by allowing a current to flow through the resistor of the heater 103 to increase the temperature of the mesa structure, which is located below the resistor, in a variation range of 0°C to several tens of °C, the phase of the first light can be varied within a range of 0° to approximately 180°. By changing the amount of current flowing through the resistor to adjust the phase difference between the first light and the second light, the output of the combined light can be set to a maximum value or to a value equal to or greater than a predetermined magnitude.

In the present modification example, a thin thermal insulation layer may be provided in the first cladding layer 14 to increase the heating efficiency of the resistor. An optical detection element, such as the monitor photodiode 101 illustrated in FIG. 10, may be provided, and the electric power supplied to the heater 103 may be adjusted according to a variation in the intensity of the combined light detected by the optical detection element, thereby reducing the phase difference.

### Fifth modification example

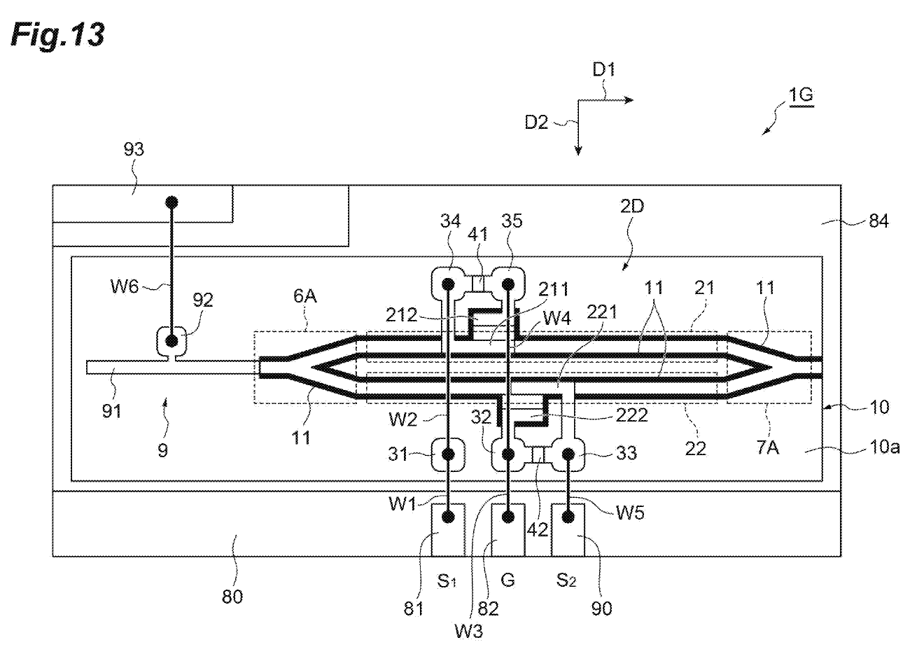

FIG. 13 is a plan view illustrating a laser device 1G according to a fifth modification example. The laser device 1G according to the present modification example differs from the laser device 1A of the above-described embodiment in the following points, and is identical to the laser device 1A in other points. The laser device 1G of the present modification example includes an optical modulator 2D instead of the optical modulator 2A of the above-described embodiment. In the optical modulator 2D, the electrode pad 33 is connected to the anode electrode 221 of the second optical modulator 22. The electrode pad 32 is connected to the cathode electrode 222 of the second optical modulator 22. In the present modification example, instead of the inverted-phase signal wiring pattern 83, a non-inverted-phase signal wiring pattern 90 is provided on the carrier 80. Further, the second modulation signal that is in the same phase as the first modulation signal is input to the electrode pad 33 of the laser device 1G from the non-inverted-phase signal wiring pattern 90 via the bonding wire W5. In FIG. 13, the first modulation signal is denoted by S₁, and the second modulation signal is denoted by S₂.

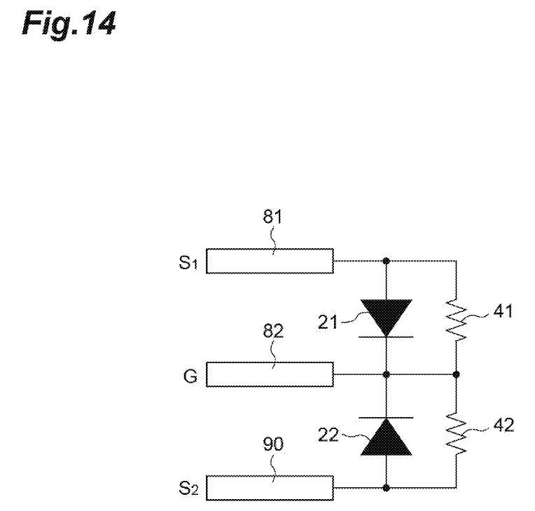

FIG. 14 is a circuit diagram illustrating an equivalent circuit of the optical modulator 2D included in the laser device 1G according to the present modification example. In FIG. 14, the first optical modulator 21 and the second optical modulator 22 are indicated by diode symbols. As illustrated in FIG. 14, in the present modification example, the first optical modulator 21 and the second optical modulator 22 are connected to each other while oriented in opposite directions. That is, the cathode of the first optical modulator 21 is connected to the cathode of the second optical modulator 22. Further, the non-inverted-phase signal wiring pattern 81 is connected to the anode of the first optical modulator 21, and the non-inverted-phase signal wiring pattern 90 is connected to the anode of the second optical modulator 22. The ground wiring pattern 82 is connected to the cathode of the first optical modulator 21 and the cathode of the second optical modulator 22.

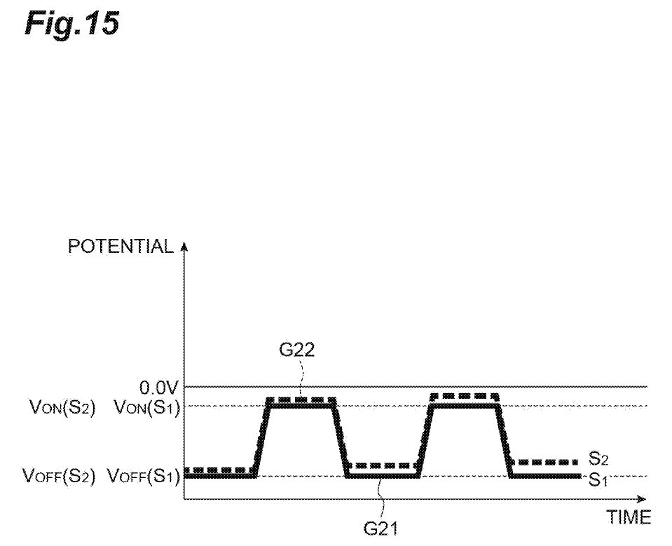

FIG. 15 is a graph illustrating a time waveform G21 of the first modulation signal applied to the first optical modulator 21, and a time waveform G22 of the second modulation signal applied to the second optical modulator 22. As illustrated in FIG. 15, the first modulation signal and the second modulation signal vary between a potential V_{OFF} and a potential V_{ON}, which is a potential higher than the potential V_{OFF}. The potential V_{OFF} and the potential V_{ON} of the first modulation signal and the second modulation signal are lower than the reference potential (0.0 V).

As in the present modification example, the second modulation signal that is in the same phase as the first modulation signal may be input to the anode electrode 221 of the second optical modulator 22, the cathode electrode 222 of the second optical modulator 22 may be set to the reference potential, and the second optical modulator 22 may be driven in the same phase as the first optical modulator 21. According to the present modification example, the drive current to be supplied to each of the first optical modulator 21 and the second optical modulator 22 is halved compared to that of a conventional single optical modulator. Thus, the impedance of each of the first optical modulator 21 and the second optical modulator 22 can be increased, and as a result, the frequency characteristics of the optical modulator 2D can be improved. Thus, the quality of the optical signal output from the optical modulator 2D can be improved.

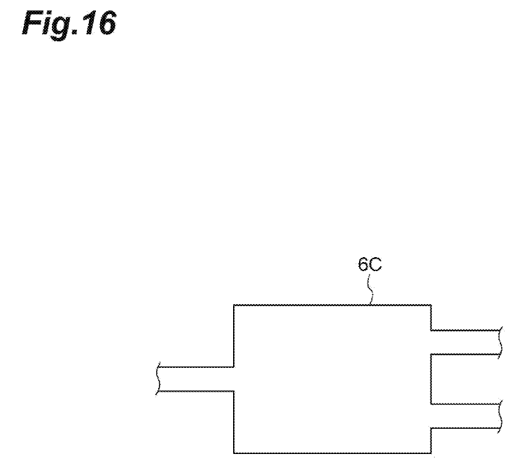

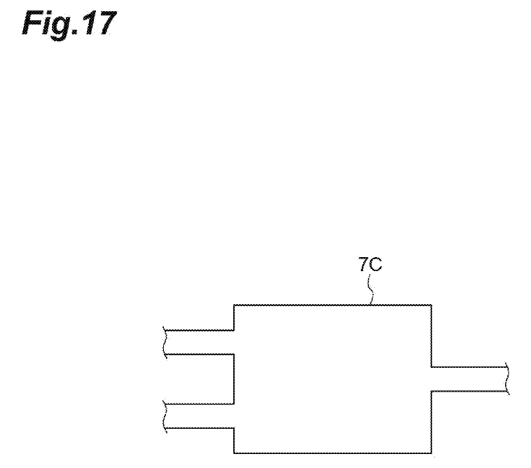

The optical modulator and the optical modulator-integrated laser device according to the present disclosure are not limited to the embodiment and each modification example described above, and can be modified in other various forms. For example, the embodiment and each modification example described above may be combined with each other in any combination. In the embodiment and each modification example described above, the optical splitter 6A including a Y-shaped optical waveguide and the optical splitter 6B including a directional coupler have been illustrated as examples of the optical splitter. The optical splitter is not limited thereto, and may be, for example, an optical splitter 6C including a multi-mode interference (MMI) coupler as illustrated in FIG. 16. In this case, light can be split with a simple structure on the substrate 10. In the embodiment and each modification example described above, the optical combiner 7A including a Y-shaped optical waveguide and the optical combiner 7B including a directional coupler have been illustrated as examples of the optical combiner. The optical combiner is not limited thereto, and may be, for example, an optical combiner 7C including an MMI coupler as illustrated in FIG. 17. In this case, light can be combined with a simple structure on the substrate 10.

In the embodiment and each modification example described above, a case where the first cladding layer 14 is n-type and the second cladding layer 16 is p-type has been illustrated as an example; however, the first cladding layer 14 may be p-type, and the second cladding layer 16 may be n-type. In that case, the polarities of the first modulation signal and the second modulation signal are reversed from those in the above-described embodiment. That is, the second modulation signal serves as the non-inverted-phase signal, and the first modulation signal serves as the inverted-phase signal.

In the embodiment and each modification example described above, an InP-based semiconductor has been illustrated as an example of the III-V compound semiconductor, which is the constituent material of the first cladding layer 14, the light absorption layer 15, and the second cladding layer 16; however, the III-V compound semiconductor is not limited thereto. In the embodiment and each modification example described above, a silicon compound film such as a SiO₂ film or a SiN film has been illustrated as an example of the constituent material of the insulating film 85; however, the constituent material (composition) of the insulating film 85 is not limited thereto. For example, the constituent material of the insulating film 85 may be silicon oxide or silicon nitride having a composition other than that in the embodiment and each modification example, or may be silicon oxynitride.

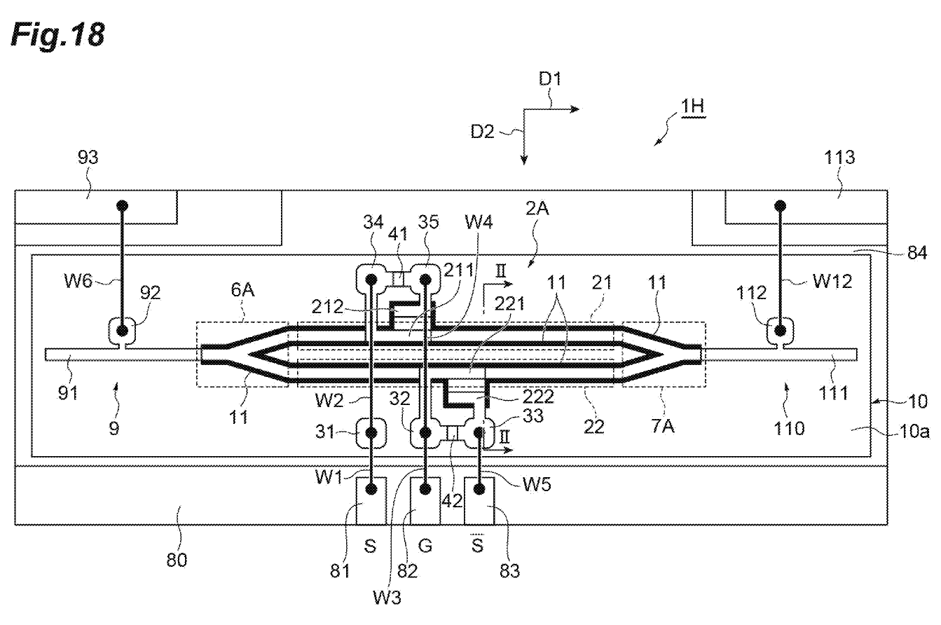

In the embodiment and each modification example described above, the optical modulator-integrated laser device may further include a semiconductor optical amplifier provided on the substrate 10. FIG. 18 is a plan view illustrating a laser device 1H including a semiconductor optical amplifier. The laser device 1H further includes a semiconductor optical amplifier 110 in addition to the configuration of the laser device 1A of the above-described embodiment. The semiconductor optical amplifier 110 is disposed on the light emission end side of the optical modulator 2A, receives, from the optical combiner 7A, the combined first light and second light, and amplifies and outputs the combined first light and second light.

The semiconductor optical amplifier 110 includes an electrode 111 and an electrode pad 112. The electrode 111 is an electrode for supplying a bias current to an active layer (not illustrated) of the semiconductor optical amplifier 110. The electrode 111 extends along the first direction D1 (the optical waveguide direction). The electrode pad 112 is disposed on a lateral side of the electrode 111, and is connected to the electrode 111. The electrode pad 112 is connected to a bias pattern 113 on the carrier 80 by a bonding wire W12. A bias current is supplied from the bias pattern 113 to the electrode 111 via the bonding wire W12 and the electrode pad 112.

As described above, the optical modulator-integrated laser device may further include the semiconductor optical amplifier 110 provided on the substrate 10. Accordingly, compared to a case where the semiconductor optical amplifier is provided external to the substrate 10, the device including the optical modulator-integrated laser device can be made more compact.

In the embodiment and the modification examples, an optical modulator of an electro-absorption (EA) type made of an InP-based semiconductor has been illustrated as an example of the optical modulator; alternatively, the configuration of the present disclosure can also be applied to an optical modulator made of a Si-based semiconductor (silicon photonics).

What is claimed is:

1. An optical modulator comprising:
a semi-insulating or insulating substrate;
an optical splitter that is provided on the substrate and splits input light;
a first optical modulator of an electro-absorption type that is provided on the substrate and is configured to modulate, by a first modulation signal, first light output from the optical splitter;
a second optical modulator of an electro-absorption type that is provided on the substrate and is configured to modulate, by a second modulation signal that is in a same phase as or in inverted phase to the first modulation signal, second light output from the optical splitter; and
an optical combiner that is provided on the substrate and is configured to combine the first light output from the first optical modulator and the second light output from the second optical modulator.

2. The optical modulator according to claim 1,
wherein one or both of the optical splitter and the optical combiner include a Y-shaped optical waveguide.

3. The optical modulator according to claim 1,
wherein one or both of the optical splitter and the optical combiner include a directional coupler.

4. The optical modulator according to claim 1,
wherein one or both of the optical splitter and the optical combiner include a multi-mode interference coupler.

5. The optical modulator according to claim 1, further comprising:
at least one termination resistor that is provided on the substrate and is configured to terminate the first modulation signal and the second modulation signal.

6. The optical modulator according to claim 1,
wherein both the first optical modulator and the second optical modulator extend along a first direction, and are disposed side by side in a second direction intersecting the first direction, and
the optical modulator further comprises a semiconductor section extending along the first direction and set to a reference potential, in a region on the substrate that is located between the first optical modulator and the second optical modulator in the second direction.

7. The optical modulator according to claim 1, further comprising:
a heater provided on an optical path between the optical splitter and the first optical modulator or on an optical path between the first optical modulator and the optical combiner.

8. The optical modulator according to claim 1,
wherein a trench that reaches the substrate is formed between the first optical modulator and the second optical modulator, and
the first optical modulator and the second optical modulator are electrically isolated from each other by the trench.

9. The optical modulator according to claim 1,
wherein the first optical modulator and the second optical modulator are made of an InP-based semiconductor or a Si-based semiconductor.

10. An optical modulator-integrated laser device comprising:
the optical modulator according to claim 1; and
a laser section that is provided on the substrate and is configured to output laser light,
wherein the input light of the optical splitter is the laser light.

11. The optical modulator-integrated laser device according to claim 10, further comprising:
a semiconductor optical amplifier that is provided on the substrate, receives, from the optical combiner, the first light and the second light that are combined, and is configured to amplify and output the first light and the second light that are combined.

12. The optical modulator-integrated laser device according to claim 10,
wherein the first optical modulator and the second optical modulator are made of an InP-based semiconductor or a Si-based semiconductor.
